(19) United States
(12) Patent Application Publication
(10) Pub. No.: US 2026/0118784 A1
(43) Pub. Date: Apr. 30, 2026

(54) FORMING APPARATUS, FORMING METHOD, AND ARTICLE MANUFACTURING METHOD

(71) Applicant: CANON KABUSHIKI KAISHA, Tokyo (JP)

(72) Inventor: YOUSUKE KONDO, Tochigi (JP)

(21) Appl. No.: 18/984,126

(22) Filed: Dec. 17, 2024

(30) Foreign Application Priority Data
Dec. 25, 2023 (JP) 2023-218436

(51) Int. Cl. G03F 9/00; G03F 7/00

(52) U.S. Cl. CPC G03F 9/7042; G03F 7/0002; G03F 9/7092

(57) ABSTRACT

A forming apparatus is provided. An application module performs detection of an end portion of a substrate and detection of a pattern region of the substrate, and applies a formable material to an application region of the substrate decided based on the detected pattern region. A planarization module performs detection of the end portion of the substrate and detection of an end portion of a member, and performs the planarization using the substrate and the member. A controller performs alignment between the substrate and the member based on the end portion of the substrate, the end portion of the member, and a positional shift amount between the pattern region and an outer shape of the substrate specified based on the end portion of the substrate detected in the application module.

### BACKGROUND OF THE INVENTION

### Field of the Invention

The present invention relates to a forming apparatus, a forming method, and an article manufacturing method.

### Description of the Related Art

As a technique capable of producing a microstructured device according to a design rule on the nanometer order and suitable for mass production, an imprint lithography (to be simply referred to as "imprint" hereinafter) technique is being put into practical use. The imprint technique is a technique in which a mold (to be also referred to as a template) including a pattern having a nanometer-scale concave-convex structure formed using an electron beam drawing apparatus, a semiconductor exposure apparatus, or the like is brought into contact with an imprint material on a substrate to transfer the pattern. A photo-curing method is one example of the imprint technique. An imprint apparatus employing the photo-curing method forms, by using a mold, a photo-curable imprint material supplied to a shot region on a substrate, cures the imprint material by light irradiation, and separates the mold from the cured imprint material, thereby forming a pattern on the substrate.

With respect to an imprint apparatus, an imprint sequence for forming a pattern for one substrate by repeating imprinting by a step-and-repeat method, similar to an exposure apparatus, has been examined. However, to improve throughput, a bulk imprinting method of forming a pattern for one substrate by one imprint process using a mold of the same size as that of the substrate has also been examined.

In recent years, there has been proposed a technique of planarizing a formable material on a substrate using a flat member without any pattern by applying the imprint technique (see, for example, Japanese Patent Laid-Open No. 2022-514245). Japanese Patent Laid-Open No. 2022-514245 describes a technique of adjusting an amount of drops of the formable material based on a step of the substrate in order to improve accuracy of planarization.

In this planarization technique, after separating a member from a cured formable material, a baking treatment is performed to add heat resistance of the formed planarization film.

The above-described forming apparatus that performs the planarization process can include an application module configured to apply a formable material to a substrate, and a planarization module configured to planarize the formable material by bringing a member into contact with the formable material applied to the substrate by the application module. In this case, alignment accuracy between a member and an application region as a region where the formable material is applied to the substrate by the application module may become a problem for the planarization module.

### SUMMARY OF THE INVENTION

The present disclosure provides, for example, a forming apparatus advantageous in correct alignment between a member and an application region of a formable material on a substrate.

The present invention in its one aspect provides a forming apparatus including an application module configured to apply a formable material onto a substrate including a mark, a planarization module configured to planarize the formable material by bringing a flat surface of a member into contact with the formable material on the substrate, and a controller, wherein the application module is configured to perform detection of an end portion of the substrate in the application module and detection of a pattern region of the substrate by detecting the mark, and apply the formable material to an application region of the substrate decided based on the detected pattern region, the planarization module is configured to perform detection of the end portion of the substrate in the planarization module and detection of an end portion of the member, and perform the planarization using the substrate and the member, and the controller is configured to perform alignment between the substrate and the member in the planarization module based on the end portion of the substrate, the end portion of the member, and a positional shift amount between the pattern region and an outer shape of the substrate specified based on the end portion of the substrate detected in the application module.

Further features of the present invention will become apparent from the following description of exemplary embodiments (with reference to the attached drawings).

### BRIEF DESCRIPTION OF THE DRAWINGS

FIG. 1 is a view showing the configuration of a forming apparatus;

FIG. 2 is a view showing the configuration of an application module;

FIG. 3 is a view showing the configuration of a planarization module;

FIG. 4 is a view showing the configuration of a heat-treatment module;

FIG. 5 is a side view showing the configuration of a member;

FIG. 6 is a flowchart illustrating a planarization process; and

FIG. 7 is a schematic view for explaining position correction between the member and a substrate.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

### First Embodiment

The present disclosure is related to a forming apparatus that performs a forming process of forming a formable material (curable composition) on a substrate. The forming process can include a contact step of bringing a member and the formable material supplied onto the substrate into contact with each other. This contact step forms the formable material. The forming process can further include the first curing step of curing the formable material in a state in which the formable material and the member are in contact with each other, a separation step of separating the cured formable material and the member, and the second curing step of further curing the formed formable material after the separation step.

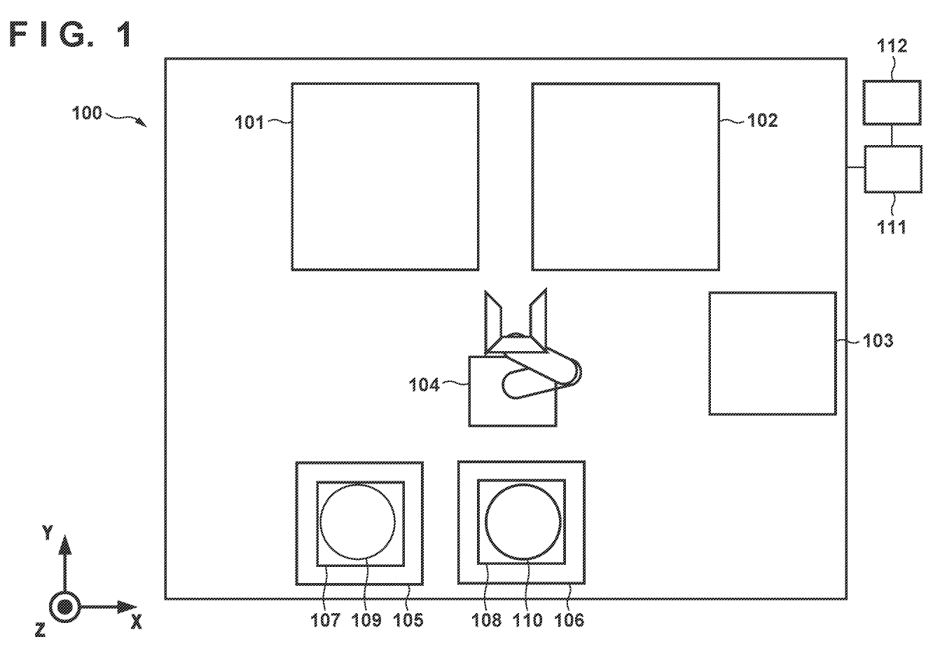

FIG. 1 is a schematic view showing the configuration of a forming apparatus 100 according to an embodiment. In this specification and the accompanying drawings, directions are indicated on an XYZ coordinate system having a horizontal plane as the X-Y plane. In general, a substrate 110 that is a substrate to be processed is placed on a substrate stage so that the surface of the substrate is parallel to the horizontal plane (X-Y plane). In the following description, directions orthogonal to each other within the plane along the surface of the substrate 110 placed on the substrate stage are set as the X-axis and the Y-axis, respectively, and a direction perpendicular to the X-axis and the Y-axis is set as the Z-axis. Directions parallel to the X-axis, the Y-axis, and the Z-axis of the XYZ coordinate system are the X direction, the Y direction, and the Z direction, respectively.

As the substrate 110, for example, a known substrate made of aluminum, a titanium-tungsten alloy, an aluminum-silicon alloy, an aluminum-copper-silicon alloy, silicon oxide, sapphire, silicon nitride, or the like can be used. The substrate 110 can be a substrate in which an adhesive layer is formed by a surface treatment such as silane coupling treatment, silazane treatment, or deposition of a thin organic film. An example of using a silicon wafer used in semiconductor manufacturing will be described as the substrate 110 below but the present invention is not limited to this. A typical wafer has a circular outer shape with a diameter of 300 mm or 200 mm, and can include a V-shaped notch that is formed in the wafer to indicate the crystal orientation of the wafer.

In this embodiment, for example, a member having a thickness of 0.25 (inclusive) to 2 mm (exclusive) is used as a member 109. The member 109 is made of a material that can transmit ultraviolet rays. Quartz is used in this embodiment, but the present invention is not limited to this. Glass, Polymethyl Methacrylate (PMMA), a polycarbonate resin, or the like may be used as the material of the member 109. In the case of an imprint apparatus, a pattern such as a circuit pattern is formed in a mold. However, the member 109 used by the forming apparatus includes no such pattern. The member 109 is a member having a flat surface (plane) to be used. The member 109 having the flat surface, which is used by the forming apparatus (planarization apparatus), is called a superstrate. Alternatively, such member is also called a pressing member, a flat plate, or the like.

FIG. 5 is a side view of the member 109. As shown in FIG. 5, in the member 109, a tapered surface that connects a side end face to a flat surface forming a lower surface facing the substrate 110 is formed. The member 109 can include a central region 501 forming a flat surface, and tapered edge regions 502 provided on the outer peripheral portion of the central region 501 to form tapered surfaces.

The main items of planarization performance are flatness, a film thickness, a defect, and the like, and may probably become problems particularly in the outer peripheral portion of a planarization film. If, for example, the application amount of the formable material is small or an application area is narrow, the member 109 and the substrate 110 may contact each other without intervention of the formable material to cause a particle or defect, or this may affect the durability of the member 109 or the substrate 110. Such contact between the member 109 and the substrate 110 without intervention of the formable material is called dry contact. To the contrary, if, for example, the application amount of the formable material is large or the application area is wide, the formable material extrudes from between the member 109 and the substrate 110. This extrusion may spread around the side surface and lower surface of the substrate 110 to contaminate the apparatus. Alternatively, the extrusion may result in a case where the cured formable material adheres to the member 109 when separating the formable material from the member 109, thereby affecting the planarization performance in a subsequent planarization process. The extrusion may become a cause of a defect when the cured formable material drops on the substrate.

The tapered edge regions 502 of the member 109 are provided to prevent such trouble in the outer peripheral portion of the planarization film. By providing the tapered edge regions 502, even if the formable material extrudes from between the member 109 and the substrate 110, the film thickness of the formable material increases in the tapered edge regions 502, thereby making it possible to suppress the spread amount of the formable material in a radial direction.

An example in which the member 109 has a circular outer shape of the same size as that of the substrate 110 will now be described but the present invention is not limited to this. For example, the member 109 including the central region 501 and the tapered edge regions 502 may have, for example, a circular outer shape with a diameter of 300 mm (inclusive) to 500 mm (exclusive). An average taper angle 503 of the tapered portion over the tapered edge region 502 is, for example, 20° or less. The taper angle may be the same over the tapered edge region. Alternatively, the taper angle may change in the tapered region. For example, in the tapered region, the taper angle may increase toward the outer edge. In this embodiment, the tapered edge region 502 of the member 109 can have a length of at least 1.0 mm in the radial direction.

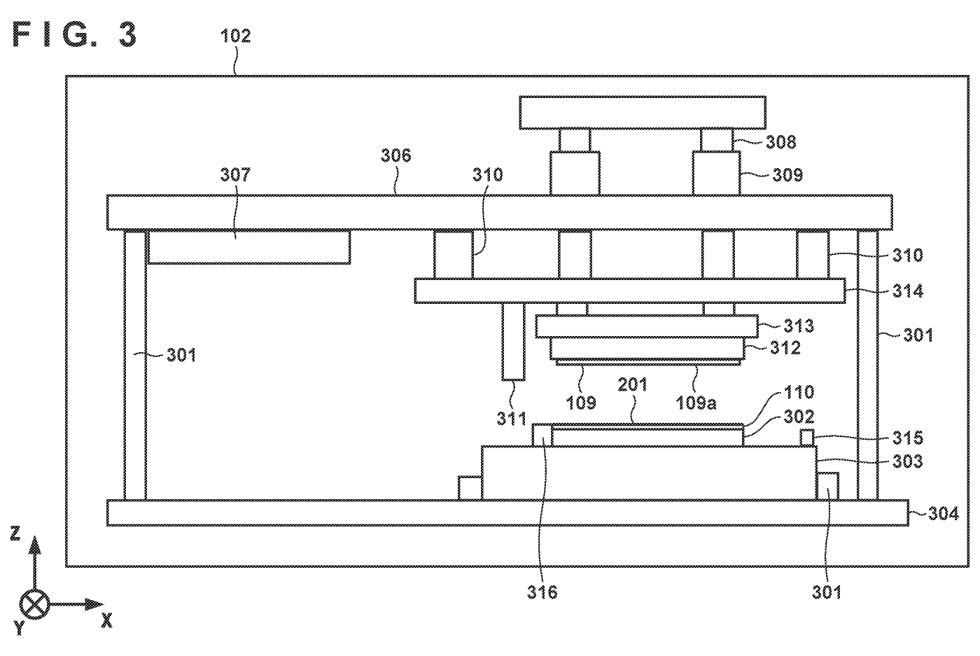

A member storage portion 105 stores a member carrier 107 that holds the plurality of members 109. A conveyance mechanism 104 is configured to convey the member 109 between a member chuck 312 (FIG. 3) of a planarization module 102 and the member carrier 107 (an arbitrary slot thereof) attached to the member storage portion 105.

A substrate storage portion 106 stores a substrate carrier 108 that holds the plurality of substrates 110. The conveyance mechanism 104 is configured to convey the substrate 110 between the following units.

(a) The substrate carrier 108 (an arbitrary slot thereof) attached to the substrate storage portion 106

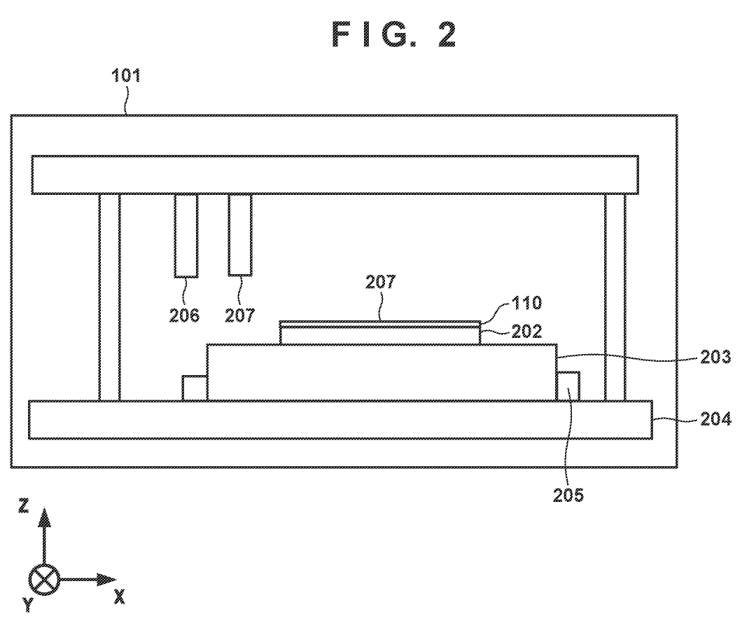

(b) A substrate chuck 202 (FIG. 2) of an application module 101

(c) A substrate chuck 302 (FIG. 3) of the planarization module 102

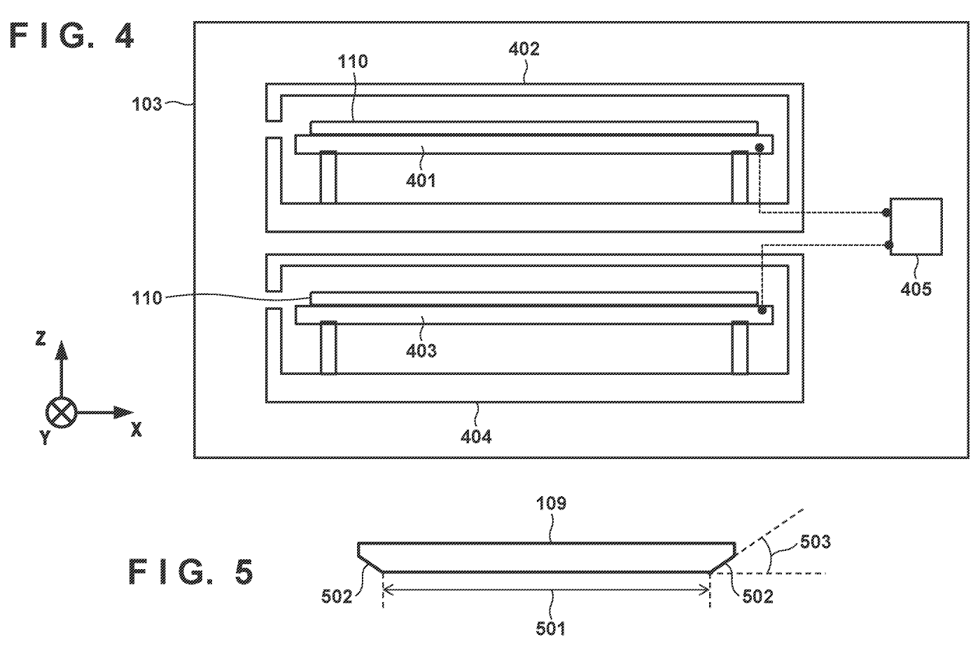

(d) A heating chuck 401 (FIG. 4) of a heat-treatment module 103

(e) A cooling chuck 403 (FIG. 4) of the heat-treatment module 103

The conveyance mechanism 104 may include the first hand that holds the substrate 110 to be loaded into the chuck of any of the units, and the second hand that collects the substrate 110 from this chuck or the chuck of another unit. In this case, it is possible to convey two substrates 110 at once.

A controller 111 can include a processor such as a CPU, a storage unit such as a RAM, a ROM, or an HDD, and an interface unit for connecting an external device and the processor. The interface unit also includes a communication interface for communicating with a host computer 112. The host computer 112 can be, for example, a computer that controls the whole factory or one region of the factory in which the forming apparatus 100 is arranged. The processor of the controller 111 controls the operation of the forming apparatus 100 by executing a program stored in the storage unit. The controller 111 may include a plurality of circuit boards. All or part of the controller 111 may be arranged on a rack in the chamber (housing) of the forming apparatus 100 or may be arranged outside the chamber.

The forming apparatus 100 can include the application module 101, the planarization module 102, and the heat-treatment module 103. In the forming apparatus 100, the application module 101, the planarization module 102, and the heat-treatment module 103 are configured as separate modules. In this embodiment, assume that the number of application modules 101, the number of planarization modules 102, and the number of heat-treatment modules 103 are all one. However, the plurality of application modules 101, the plurality of planarization modules 102, and the plurality of heat-treatment modules 103 may be arranged. In addition, the forming apparatus 100 may include a pre-alignment unit that adjusts at least one (pre-alignment state) of the position and direction of the substrate 110 so as to convey the substrate 110 at an almost correct position in an almost correct direction with respect to each module. For example, the pre-alignment unit can obtain the position and direction of the substrate 110 by detecting an orientation flat for indicating the crystal orientation of the substrate, a notch position, or the outer shape of the substrate. If the substrate 110 includes a pattern, the pre-alignment unit may be configured to obtain the position and direction of the substrate 110 based on the detected pattern.

FIG. 2 shows the configuration of the application module 101. The application module 101 applies (supplies or arranges) a formable material 201 onto the substrate 110. The application module 101 can perform detection of the end portion of the substrate 110 in the application module 101, and detection of the pattern region of the substrate 110 by detecting a mark formed on the substrate 110. The application module 101 is configured to apply the formable material 201 to the application region of the substrate 110 decided based on the detected pattern region.

As the formable material 201, an ultraviolet-curable or thermosetting composition (for example, a resin) is used. The formable material 201 may contain any of a polymerizable compound, a photopolymerization initiator, a nonpolymerizable compound, and a solvent. The nonpolymerizable compound may include at least one of a sensitizer, a hydrogen donor, an internal mold release agent, a surfactant, an antioxidant, and a polymer component. The formable material 201 according to this embodiment is, for example, a curable composition that is cured by irradiation with light (ultraviolet rays) having a wavelength of 200 to 380 nm.

The application module 101 includes a dispenser 206 that supplies the formable material. The dispenser 206 includes a nozzle (discharge portion) that discharges a droplet of the formable material 201 onto the substrate 110. As a discharge method, a piezo-jet method or a micro-solenoid method can be used. The number of nozzles is not particularly limited, and a nozzle array including one row or a plurality of rows may be arranged.

A substrate stage 203 (first substrate stage) can move on a base 204 while making the substrate chuck 202 hold the substrate 110. As a driver 205 that drives the substrate stage 203, a linear motor is used in this embodiment. However, the present invention is not limited to this, and a known technique such as a driving mechanism formed by combining a ball screw and a rotation motor can be applied. The moving directions of the substrate stage 203 can be three axis directions including the X direction, the Y direction, and a rotation about the Z-axis. Alternatively, the moving directions of the substrate stage 203 may be six axis directions including the Z direction, a rotation about the X-axis, and a rotation about the Y-axis in addition to the above three axis directions. A desired application pattern can be applied to the substrate 110 by applying the formable material 201 to the substrate 110 by the dispenser 206 while scanning the substrate stage 203 on the X-Y plane.

The application module 101 includes an off-axis scope 207 (first measurement portion). The off-axis scope 207 can detect a reference mark arranged on the substrate stage 203, and a mark formed on the substrate 110 mounted on the substrate stage 203. The mark of the substrate 110 is a mark that can be used to specify the position of the pattern region of the substrate 110. The controller 111 obtains the relative position between the reference mark and the substrate 110 with reference to the mark of the substrate 110 based on the result of the detection of the reference mark of the substrate stage 203 and the mark of the substrate 110 by the off-axis scope 207. The controller 111 adjusts the position of at least one of the dispenser 206 and the substrate stage 203 based on the measured relative position. This can apply the formable material by arranging the dispenser 206 and the substrate 110 at a desired relative position. The off-axis scope 207 can include a light source, an image sensor, and an optical system for guiding detection light to a subject and guiding light reflected by the subject to the image sensor.

The off-axis scope 207 can further detect the end portion of the substrate 110 mounted on the substrate stage 203. The controller 111 can obtain, based on the result of the detection of the end portion of the substrate 110 by the off-axis scope 207, the first center position as a center position (the center position of the outer shape reference) based on the outer shape of the substrate 110. For example, the controller 111 can obtain the center position of the outer shape reference of the substrate 110 by measuring the end portion of the substrate 110 at three or more points using the off-axis scope 207. In a case where the radius of the substrate 110 is already known, measurement may be performed at two points. Furthermore, the controller 111 can measure the relative position between the substrate 110 and the reference mark of the substrate stage 203 by the outer shape reference of the substrate 110 using the off-axis scope 207. The controller 111 can obtain the relative position of the mark position with respect to the outer shape position (the relative position between the outer shape and the mark) by calculating the difference between the relative position of the mark reference and the relative position of the outer shape reference. The relative position of the outer shape reference may be measured by measuring the upper surface of the substrate 110 by a distance sensor and detecting a step of the end portion of the substrate 110.

In addition, using the off-axis scope 207, the controller 111 can obtain the second center position as the center position (the center position of the mark reference) of the pattern region decided based on the mark of the substrate 110.

FIG. 3 shows the configuration of the planarization module 102. The planarization module 102 can perform detection of the end portion of the substrate 110 in the planarization module 102 and detection of the end portion of the member 109. The planarization module 102 is also configured to perform planarization using the substrate 110 and the member 109 aligned based on the results of the detection of the end portion of the substrate 110 and the detection of the end portion of the member 109.

The planarization module 102 forms the formable material 201 applied onto the substrate 110 by the application module 101. The planarization module 102 includes an irradiator 307 that performs irradiation with light for curing the formable material 201 on the substrate 110. The irradiator 307 includes a light source, and can include an optical system including a lens and a mirror for guiding light from the light source. A substrate stage 303 (second substrate stage) supports the substrate chuck 302 (substrate holding portion) for holding the substrate 110. A planarization head 313 supports the member chuck 312 for holding the member 109. Drivers 309 drive the planarization head 313 in a vertical direction (Z direction), and guides 308 guide movement of the planarization head 313 in the vertical direction.

The controller 111 controls the drivers 309 to bring a surface 109a of the member 109 into contact with the formable material 201 on the substrate 110, and then separates the member 109 from the member chuck 312. The controller 111 drives the substrate stage 303 to locate the substrate 110 and the member 109 below the irradiator 307. The controller 111 controls the irradiator 307 to irradiate the formable material 201 with light in this state. This cures the formable material 201.

After that, the controller 111 drives the substrate stage 303 to locate the substrate 110 and the member 109 below the member chuck 312. The controller 111 moves the member chuck 312 downward in this state, thereby causing the member chuck 312 to hold the member 109. After that, the controller 111 controls the drivers 309 to move the member 109 upward, thereby separating the member 109 from the formable material 201. Thus, a cured product having a surface shape corresponding to the contact surface of the member 109 is formed on the substrate 110. In this way, the planarization module 102 forms the formable material 201.

The substrate stage 303 can move on a base 304 in a state in which the substrate chuck 302 holds the substrate 110. When the substrate 110 is loaded/unloaded into/from the substrate chuck 302, it becomes easy to avoid interference (physical contact) between the conveyance mechanism 104 and the planarization head 313 by moving the substrate stage 303 to a position separated from the lower portion of the planarization head 313. Furthermore, it is possible to finely adjust the relative position between the member 109 and the substrate 110 by moving the substrate stage 303 only by a small amount before bringing the member 109 and the formable material 201 on the substrate 110 into contact with each other. As a driver 305 that drives the substrate stage 303, a linear motor is used in this embodiment. However, the present invention is not limited to this, and a known technique such as a driving mechanism formed by combining a ball screw and a rotation motor can be applied. In this embodiment, the moving directions of the substrate stage 303 are two axis directions including the X direction and the Y direction. However, the present invention is not limited to this, and the moving directions may be six axis directions. The substrate stage 303 may include a top plate, and a plane-shaped member connected to the top plate. A separation assist mechanism 316 for assisting separation is arranged on the substrate stage 303. The separation assist mechanism 316 is driven upward in the Z direction so as to pass through a notch portion used to circumferentially locate the substrate 110, and contacts the member 109 to push up the member 109, thereby assisting separation.

The substrate chuck 302 is fixed to the substrate stage 303 by fastening or suction. The substrate chuck 302 includes a holding surface that holds the substrate 110. As a method of holding the substrate 110 by the substrate chuck 302, a known technique such as a vacuum suction method or an electrostatic attraction method can be applied. In the case of the vacuum suction method, a negative pressure generation apparatus and a concave portion (groove) formed in the surface of the substrate chuck 302 communicate with each other. By setting a negative pressure inside the concave portion in a state in which the substrate 110 is placed on the holding surface, it is possible to hold the substrate 110.

The member chuck 312 (member holding portion) includes a holding surface that holds the member 109, and holds the member 109 by a known technique such as a vacuum suction method or an electrostatic attraction method.

A plurality of columns 301 are arranged on the base 304, and used to support a structure 306. The structure 306 may be a top plate. Although the four columns 301 are arranged in this embodiment (only two columns are shown in FIG. 3), the present invention is not limited to this. A suspension stand 314 suspends (supports) the structure 306 via columns 310. In addition, an off-axis scope 311 is attached to the suspension stand 314. Openings for allowing the above-described guides 308 to extend through are formed in the structure 306 and the suspension stand 314.

The planarization module 102 includes the off-axis scope 311. The off-axis scope 311 can detect the end portion of the substrate 110 mounted on the substrate stage 303. The off-axis scope 311 can be used as the second measurement portion for obtaining the third center position as a center position decided based on the outer shape of the substrate. The off-axis scope 311 includes a light source, an image sensor, and an optical system for guiding detection light to a subject and guiding light reflected by the subject to the image sensor. By arranging a plurality of off-axis scopes 311 in the Y direction, it is possible to reduce the driving range of the substrate stage 303 in the Y direction to a range necessary for alignment between the member 109 and the substrate 110. For example, the first off-axis scope is arranged at a position of Y = 50 mm and the second off-axis scope is arranged at a position of Y = -50 mm. The controller 111 step-moves the substrate stage 303 in the X direction, and the off-axis scopes 311 including the first and second off-axis scopes are used to measure the end portion of the substrate 110 at three or more points. Based on the result of the detection of the end portion of the substrate 110 by the scopes, the controller 111 can obtain the third center position as a center position (the center position of the outer shape reference) decided based on the outer shape of the substrate 110. In a case where the radius of the substrate 110 is already known, measurement may be performed at two points. The center position of the outer shape reference of the substrate 110 may be measured by a method of measuring the upper surface of the substrate 110 by a distance sensor and detecting a step of the end portion of the substrate 110.

The planarization module 102 includes an upward sensor 315. The upward sensor 315 detects the member 109 located on the upper side. As the upward sensor 315, a measuring device for measuring a distance, that is called a displacement sensor or a gap sensor using an interference method, can be used. The upward sensor 315 can be used as the third measurement portion for obtaining the fourth center position as a center position (the center position of the outer shape reference) decided based on the outer shape of the member 109. By arranging a plurality of upward sensors 315 in the Y direction, it is possible to reduce the driving range of the substrate stage 303 in the Y direction to a range necessary for alignment between the member 109 and the substrate 110. For example, the first upward sensor is arranged at a position of Y = +50 mm and the second upward sensor is arranged at a position of Y = -50 mm. The controller 111 step-moves the substrate stage 303 in the X direction, and the upward sensors 315 including the first and second upward sensors are used to measure the end portion of the member 109 at three or more points. The controller 111 can obtain the center position of the outer shape reference of the member 109 based on the result of detection of the end portion of the member 109 by the upward sensors 315. In a case where the radius of the member 109 is already known, measurement may be performed at two points. The end portion of the member 109 may be measured by capturing the member 109 using a scope including a light source, an image sensor, and an optical system for guiding detection light to a subject or the image sensor.

FIG. 4 shows the configuration of the heat-treatment module 103. The heat-treatment module 103 accelerates curing of the formable material 201 planarized on the substrate 110. The heat-treatment module 103 can include the heating chuck 401 that holds and heats the substrate 110, and a heating chamber 402 arranged to surround the heating chuck 401. The heat-treatment module 103 can further include the cooling chuck 403 that holds and cools the substrate 110, and a cooling chamber 404 arranged to surround the cooling chuck 403.

The heating chuck 401 holds the substrate 110, and heats the substrate 110. The heating chuck 401 needs to have high thermal conductivity from a viewpoint of acceleration of the increase and decrease in temperature. The thermal conductivity is desirably, for example, 150 W/m⋅K or more. The heating chuck 401 heats the substrate 110 by heating a heating element by power supplied from a power supply unit 405. However, the heating method is not limited to this. For example, a heating method of irradiating the substrate 110 with infrared rays may be adopted.

The heating chamber 402 is arranged to surround the heating chuck 401. At the time of heating by the heating chuck 401, the heating chamber 402 can desirably form a closed space. Furthermore, since air desirably flows in/out from the heating chamber 402 as little as possible, the opening of the heating chamber 402 for loading/unloading the substrate 110 is desirably as small as possible and the opening is desirably opened/closed within a short time.

The cooling chuck 403 holds the substrate 110, and cools the substrate 110. The cooling chuck 403 is controlled to a temperature lower than that of the heating chuck 401, and cools the substrate 110 heated by the heating chuck 401 before conveying it to the substrate carrier 108. The cooling chamber 404 is arranged to surround the cooling chuck 403.

The configuration of the forming apparatus 100 is generally as described above. The forming apparatus 100 is configured to perform, by different modules, that is, different substrate stages, application of the formable material onto the substrate and planarization of bringing the member into contact with the formable material on the substrate. In this configuration, the application module 101 aligns the application region of the formable material 201 with the pattern region of the substrate 110 using the off-axis scope 207 as a pattern measurement means for measuring the pattern region of the substrate 110. On the other hand, the planarization module 102 does not include the pattern measurement means of the substrate. The planarization module 102 aligns the member 109 and the substrate 110 based on the outer shape of the member 109 and that of the substrate 110. However, the center position of the outer shape reference of the substrate 110 and that of the pattern region of the substrate 110 do not always match each other. Therefore, it is difficult for the conventional planarization module to correctly align the member and the application region of the formable material on the substrate.

It is considered to provide a pattern measurement means similar to that of the application module 101 in the planarization module 102 but this increases the cost and the size of the apparatus. This embodiment implements correct alignment between the member and the application region of the formable material on the substrate in the planarization module having no such pattern measurement means.

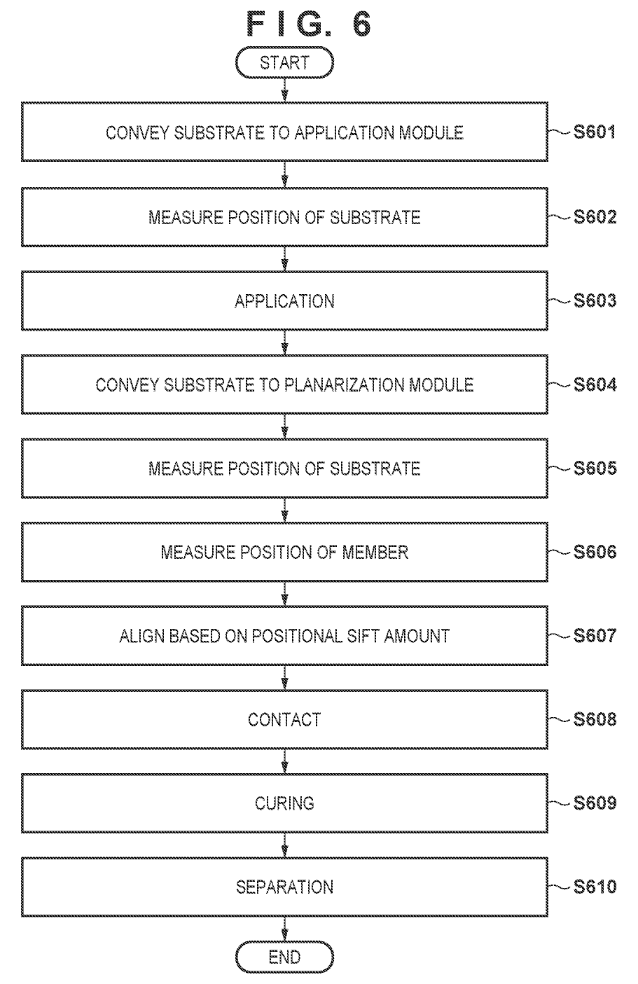

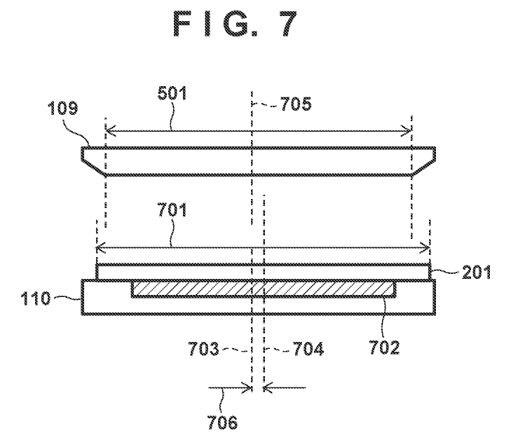

A forming process (planarization process) by the forming apparatus 100 will be described with reference to FIGS. 6 and 7. FIG. 6 is a flowchart of the forming process (planarization process) by the forming apparatus 100. FIG. 7 is a schematic view for explaining position correction between the member 109 and the substrate 110.

In step S601, the controller 111 controls the conveyance mechanism 104 to unload the substrate 110 from the substrate carrier 108 and load the substrate 110 into the application module 101. The substrate 110 is held by the substrate chuck 202. In step S602 (first step), the controller 111 measures (detects), using the off-axis scope 207, the end portion of the substrate 110 held by the substrate chuck 202, thereby obtaining a center position 703 (first center position) of the outer shape reference of the substrate 110. Furthermore, the controller 111 detects, using the off-axis scope 207, the mark formed on the substrate 110, thereby obtaining a center position 704 (second center position) of the mark reference of the substrate 110. The difference between the center position 703 of the outer shape reference and the center position 704 of the mark reference indicates a positional shift amount 706 between the outer shape of the substrate and the mark (that is, the pattern region). The mark formed on the substrate 110 may be measured using the off-axis scope 207, and the center position 703 of the outer shape reference may be reflected on the position of the substrate stage 203 when measuring the substrate 110. In this case, the measured value indicates the positional shift amount 706 between the outer shape of the substrate and the mark.

If the variation of the difference between the center position 703 of the outer shape reference of the substrate 110 and the center position 704 of the mark reference of the substrate 110 is small with respect to the alignment accuracy at the time of contact in one lot, the center position 703 of the outer shape reference of the substrate 110 may be measured once in one lot.

In step S603 (second step), the controller 111 executes application of the formable material 201 to the substrate 110 in the application module 101. At this time, the discharge position of the formable material 201 from the dispenser 206 is adjusted with respect to the center position 704 of the mark reference of the substrate 110 obtained by the measurement in step S602. This aligns an application region 701 of the formable material 201 with a pattern region 702 of the substrate. In this way, in step S603, the formable material is applied to the application region of the substrate decided based on the detected pattern region. To avoid dry contact in which the central region 501 contacts the substrate 110 without intervention of the formable material 201, the application module 101 applies the formable material so that the application region 701 becomes larger than the central region 501 (flat surface) so as to include the central region 501 of the member 109.

In step S604, the controller 111 controls the conveyance mechanism 104 to unload the substrate 110 from the application module 101 and load it into the planarization module 102. The substrate 110 is held by the substrate chuck 302.

Steps S605 and S606 correspond to the third step including performing detection of the end portion of the substrate 110 and detection of the end portion of the member 109 in the planarization module 102. In step S605, the controller 111 measures (detects), using the off-axis scope 311, the end portion of the substrate 110 held by the substrate chuck 302, thereby obtaining the center position 703 (third center position) of the outer shape reference of the substrate 110. Assume that if the substrate chuck holds the substrate 110 so that the center of the substrate chuck matches the center position 703 of the outer shape reference of the substrate, the planarization module 102 is adjusted so as to measure the center position 703 of the outer shape reference of the substrate as (0, 0) mm. In step S606, the controller 111 measures, using the upward sensor 315, the end portion of the member 109 held by the member chuck 312, thereby obtaining a center position 705 (fourth center position) of the outer shape reference of the member 109. Assume that if the member chuck 312 holds the member 109 so that the center position of the member chuck 312 matches the center position of the member 109, the planarization module 102 is adjusted so as to measure the center position of the outer shape reference of the member 109 as (0, 0) mm.

In step S607 (fourth step), the controller 111 aligns the substrate 110 and the member 109 based on the positional shift amount between the pattern region 702 and the outer shape of the substrate 110 specified based on the end portion of the substrate 110 detected in step S602. More specifically, the controller 111 aligns the substrate 110 and the member 109 based on a value obtained by adding the positional shift amount 706 to the difference between the center position of the outer shape reference of the member 109 and the center position 703 of the outer shape reference of the substrate 110 obtained in step S605.

Steps S608 to S610 performed after step S607 (fourth step) correspond to the fifth step of performing planarization of the formable material by bringing the flat surface of the member 109 into contact with the formable material on the substrate 110. In step S608, the controller 111 controls the driver 309 to bring the surface 109a of the member 109 into contact with the formable material 201 on the substrate 110. Assume that the planarization module 102 is adjusted so as to perform the contact process in a state in which the center position 703 matches the center position 705 when the center position 705 of the outer shape reference of the member is (0, 0) mm and the center position 703 of the outer shape reference of the substrate is (0, 0) mm. As described above, the alignment between the substrate 110 and the member 109 in step S607 is performed in consideration of the positional shift amount between the outer shape of the substrate 110 and the pattern region 702. Therefore, the contact process can be performed in a state in which the center position 704 of the mark reference of the substrate 110 matches the center position 705 of the outer shape reference of the member 109.

Note that if the positional shift amount 706 falls within the measurement accuracy, it is not essential to consider the positional shift amount 706 in step S607. If the application region 701 is smaller than the central region 501 of the member 109, the positional shift amount 706 measured in step S602 may or may not be considered in step S607 in addition to the position of the substrate stage 303 at the time of contact. If the positional shift amount 706 is considered in step S607, the contact process is performed in a state in which the center position 704 of the mark reference of the substrate 110 matches the center position 705 of the outer shape reference of the member 109. If the positional shift amount 706 is not considered in step S607, the contact process is performed in a state in which the center position 703 of the outer shape reference of the substrate 110 matches the center position 705 of the outer shape reference of the member 109.

After the contact process sufficiently progresses, the controller 111 causes the member chuck 312 to temporarily dechuck the member 109, and controls the driver 309 to move the member chuck 312 upward. This simply places the member 109 on the formable material 201.

In step S609, the controller 111 controls the substrate stage 303 to locate the substrate 110 and the member 109 below the irradiator 307, and controls the irradiator 307 to irradiate the formable material 201 with light, thereby curing the formable material 201.

In step S610, the controller 111 controls the substrate stage 303 to locate the substrate 110 and the member 109 below the member chuck 312, and controls the driver 309 to move the member chuck 312 downward, thereby causing the member chuck 312 to hold the member 109 again. After that, the controller 111 controls the driver 309 to move the member chuck 312 upward, and separates the member 109 from the cured formable material 201.

With the above process, even if the planarization module 102 does not include the pattern measurement means of the substrate, it is possible to implement correct alignment between the member and the formable material.

### Embodiment of Article Manufacturing Method

A method of manufacturing an article (a semiconductor IC element, a liquid crystal display element, a color filter, a MEMS, or the like) by using the above-described forming apparatus will be described next. The manufacturing method includes, by using a film forming apparatus as the above-described forming apparatus, a step of planarizing a composition arranged on a substrate (a wafer, a glass substrate, or the like), and a step of curing the composition. This forms a planarization film on the substrate. Then, a process such as pattern formation using a lithography apparatus is performed on the substrate with the planarization film formed thereon, and the processed substrate is processed in other known processing steps to manufacture an article. Other known steps include patterning exposure and an accompanying preprocess, etching, resist removal, dicing, bonding, and packaging. This manufacturing method can manufacture an article with higher quality than conventional methods.

The present invention is not limited to the above embodiments and various changes and modifications can be made within the spirit and scope of the present invention. Therefore, to apprise the public of the scope of the present invention, the following claims are made.

### Other Embodiments

Embodiment(s) of the present invention can also be realized by a computer of a system or apparatus that reads out and executes computer executable instructions (e.g., one or more programs) recorded on a storage medium (which may also be referred to more fully as a 'non-transitory computer-readable storage medium') to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-218436, filed December 25, 2023, which is hereby incorporated by reference herein in its entirety.

What is claimed is:

1. A forming apparatus comprising:
an application module configured to apply a formable material onto a substrate including a mark;
a planarization module configured to planarize the formable material by bringing a flat surface of a member into contact with the formable material on the substrate; and
a controller,
wherein the application module is configured to perform detection of an end portion of the substrate in the application module and detection of a pattern region of the substrate by detecting the mark, and apply the formable material to an application region of the substrate decided based on the detected pattern region,
the planarization module is configured to perform detection of the end portion of the substrate in the planarization module and detection of an end portion of the member, and perform the planarization using the substrate and the member, and
the controller is configured to perform alignment between the substrate and the member in the planarization module based on the end portion of the substrate, the end portion of the member, and a positional shift amount between the pattern region and an outer shape of the substrate specified based on the end portion of the substrate detected in the application module.

2. The apparatus according to claim 1, wherein
the application module includes a first measurement portion configured to obtain a first center position as a center position decided based on the outer shape of the substrate and a second center position as a center position of the pattern region decided based on the mark,
the planarization module includes a second measurement portion configured to obtain a third center position as a center position decided based on the outer shape of the substrate, and a third measurement portion configured to obtain a fourth center position as a center position decided based on an outer shape of the member, and
the controller is configured to perform the alignment between the substrate and the member in the planarization module based on a value obtained by obtaining the positional shift amount by calculating a difference between the first center position and the second center position, and adding the positional shift amount to a difference between the third center position and the fourth center position.

3. The apparatus according to claim 2, wherein
the application module includes a first substrate stage configured to hold the substrate,
the first measurement portion is configured to obtain the first center position and the second center position with respect to the substrate held by the first substrate stage,
the planarization module includes a second substrate stage different from the first substrate stage, and
the second measurement portion is configured to obtain the third center position with respect to the substrate held by the second substrate stage.

4. The apparatus according to claim 3, wherein
the application module further includes a dispenser configured to supply the formable material,
the first measurement portion is configured to detect a reference mark arranged on the first substrate stage and the mark of the substrate held by the first substrate stage, and
the controller is configured to obtain a relative position between the reference mark and the substrate based on the mark from a result of the detection of the reference mark and the mark by the first measurement portion, and adjust a position of at least one of the dispenser and the first substrate stage based on the relative position.

5. The apparatus according to claim 4, wherein
the first measurement portion is configured to further detect the end portion of the substrate held by the first substrate stage, and
the controller is configured to obtain the first center position based on a result of the detection of the end portion of the substrate by the first measurement portion, and obtain the second center position based on the result of the detection of the mark by the first measurement portion.

6. The apparatus according to claim 5, wherein
the second measurement portion is configured to detect the end portion of the substrate held by the second substrate stage, and
the controller is configured to obtain the third center position based on a result of the detection of the end portion of the substrate by the second measurement portion.

7. The apparatus according to claim 3, wherein
the planarization module includes a member holding portion configured to hold the member,
the third measurement portion is configured to detect the end portion of the member held by the member holding portion, and
the controller is configured to obtain the fourth center position based on a result of the detection of the end portion of the member by the third measurement portion.

8. The apparatus according to claim 1, wherein
the member is formed with a tapered surface that connects a side end face to a flat surface forming a lower surface facing the substrate, and
the application region is a region larger than the flat surface of the member.

9. A forming method of planarizing a formable material by bringing a flat surface of a member into contact with the formable material on a substrate including a mark, comprising:
causing an application module to perform detection of an end portion of the substrate and detection of a pattern region of the substrate by detecting the mark;
causing the application module to apply the formable material to an application region of the substrate decided based on the detected pattern region;
causing a planarization module to perform detection of the end portion of the substrate and detection of an end portion of the member;
causing the planarization module to perform alignment between the substrate and the member in the planarization module based on the end portion of the substrate, the end portion of the member, and a positional shift amount between the pattern region and an outer shape of the substrate specified based on the end portion of the substrate detected in the causing the application module to perform detection; and
causing, after the causing the planarization module to perform alignment, the planarization module to planarize the formable material by bringing a flat surface of the member into contact with the formable material on the substrate.

10. An article manufacturing method of manufacturing an article from a processed substrate, comprising:
causing a forming apparatus defined in claim 1 to form a film of a formable material on a substrate; and
processing the substrate on which the film has been formed in the causing the forming apparatus.
